(19) United States
(12) Patent Application Publication
(10) Pub. No.: US 2026/0142628 A1
(43) Pub. Date: May 21, 2026

(54) Class-D amplifier

(71) Applicant: REALTEK SEMICONDUCTOR CORPORATION, HSINCHU (TW)

(72) Inventors: CHE-HUNG LIN, Hsinchu (TW); Ling-Miao Chou, Hsinchu (TW); You-Min Lai, Hsinchu (TW); Ching-Hsiang Chang, Hsinchu (TW)

(21) Appl. No.: 19/353,962

(22) Filed: Oct. 9, 2025

(30) Foreign Application Priority Data
Nov. 20, 2024 (TW) 113144774

(51) Int. Cl. H03F 3/217; H03F 1/30

(52) U.S. Cl. CPC H03F 3/2171; H03F 1/305; H03F 2200/351

(57) ABSTRACT

A class-D amplifier includes a loop filter configured to receive first and second feedback signals, to receive first and second input signals through first and second resistors respectively, and to filter the first and second input signals and the first and second feedback signals to generate first and second filtered signals; a triangle wave generator configured to generate a triangle wave according to first and second reference voltages; first and second comparators configured to compare the first and second filtered signals with the triangle wave respectively to generate the first and second pulse width modulation (PWM) signals, respectively; first and second driver circuits configured to generate first and second output signals according to the first and second PWM signals, respectively; and a reference voltage generation circuit configured to generate the first and second reference voltages according to a control signal.

### BACKGROUND OF THE INVENTION

### 1. Field of the Invention

The present invention generally relates to amplifiers, and more particularly, to class-D amplifiers.

### 2. Description of Related Art

Class-D amplifiers often use loop filters to filter the input signal and the feedback signal fed back from the output terminal to the input terminal. However, in order to drive the next-stage component (e.g., a speaker), the output terminal of the class-D amplifier often operates in a higher power domain (compared to the input terminal); in other words, the voltage of the feedback signal is relatively high. A feedback signal with a relatively high voltage may cause the transistor inside the loop filter to operate in an incorrect region, which may result in errors in the loop filter or even in the entire class-D amplifier.

### SUMMARY OF THE INVENTION

In view of the issues of the prior art, an object of the present invention is to provide class-D amplifiers, so as to make an improvement to the prior art.

According to one aspect of the present invention, a class-D amplifier is provided. The class-D amplifier includes a first resistor, a second resistor, a loop filter, a triangle wave generator, a first comparator, a second comparator, a first driver circuit, a second driver circuit, a third resistor, a fourth resistor, and a reference voltage generation circuit. The loop filter is coupled to the first resistor and the second resistor, and is configured to receive a first feedback signal and a second feedback signal, as well as to receive a first input signal and a second input signal through the first resistor and the second resistor, respectively. The loop filter filters the first input signal, the second input signal, the first feedback signal, and the second feedback signal to generate a first filtered signal and a second filtered signal. The triangle wave generator is configured to generate a triangle wave according to a first reference voltage and a second reference voltage. The first comparator is coupled to the loop filter and the triangle wave generator, and is configured to compare the first filtered signal with the triangle wave to generate a first pulse width modulation (PWM) signal. The second comparator is coupled to the loop filter and the triangle wave generator, and is configured to compare the second filtered signal with the triangle wave to generate a second PWM signal. The first driver circuit is coupled to the first comparator, and is configured to generate a first output signal according to the first PWM signal. The second driver circuit is coupled to the second comparator, and is configured to generate a second output signal according to the second PWM signal. The third resistor is coupled between the first driver circuit and the loop filter. The fourth resistor is coupled between the second driver circuit and the loop filter. The reference voltage generation circuit is coupled to the triangle wave generator, and is configured to generate the first reference voltage and the second reference voltage according to a control signal.

According to another aspect of the present invention, a class-D amplifier is provided. The class-D amplifier includes a first resistor, a second resistor, a loop filter, a triangle wave generator, a first comparator, a second comparator, a first driver circuit, a second driver circuit, a third resistor, a fourth resistor, and a common-mode voltage generation circuit. The loop filter is coupled to the first resistor and the second resistor and is configured to receive a first feedback signal and a second feedback signal, as well as to receive a first input signal and a second input signal through the first resistor and the second resistor, respectively. The loop filter filters the first input signal, the second input signal, the first feedback signal, and the second feedback signal to generate a first filtered signal and a second filtered signal. The triangle wave generator is configured to generate a triangle wave according to a first reference voltage and a second reference voltage. The first comparator is coupled to the loop filter and the triangle wave generator, and is configured to compare the first filtered signal with the triangle wave to generate a first PWM signal. The second comparator is coupled to the loop filter and the triangle wave generator, and is configured to compare the second filtered signal with the triangle wave to generate a second PWM signal. The first driver circuit is coupled to the first comparator, and is configured to generate a first output signal according to the first PWM signal. The second driver circuit is coupled to the second comparator, and is configured to generate a second output signal according to the second PWM signal. The third resistor is coupled between the first driver circuit and the loop filter. The fourth resistor is coupled between the second driver circuit and the loop filter. The common-mode voltage generation circuit is coupled to the loop filter, and is configured to generate a common-mode voltage according to a control signal. The loop filter includes an integrator, which includes an operational amplifier, and the common-mode voltage is the common-mode voltage of the operational amplifier.

The technical means embodied in the embodiments of the present invention can solve at least one of the problems of the prior art. Therefore, compared to the prior art, the present invention can improve the stability of a class-D amplifier.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a functional block diagram of a class-D amplifier according to an embodiment of the present invention.

FIG. 2 is a schematic diagram of a triangle wave.

FIG. 3 is a circuit diagram of a reference voltage generation circuit according to an embodiment of the present invention.

FIG. 4 shows the relationship between a control signal and a reference voltage.

FIG. 5 is a functional block diagram of a class-D amplifier according to another embodiment of the present invention.

FIG. 6 is a circuit diagram of a loop filter according to an embodiment of the present invention.

FIG. 7 is a circuit diagram of a common-mode voltage generation circuit according to an embodiment of the present invention.

FIG. 8 is a functional block diagram of a class-D amplifier according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes class-D amplifiers. On account of that some or all elements of the class-D amplifiers could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

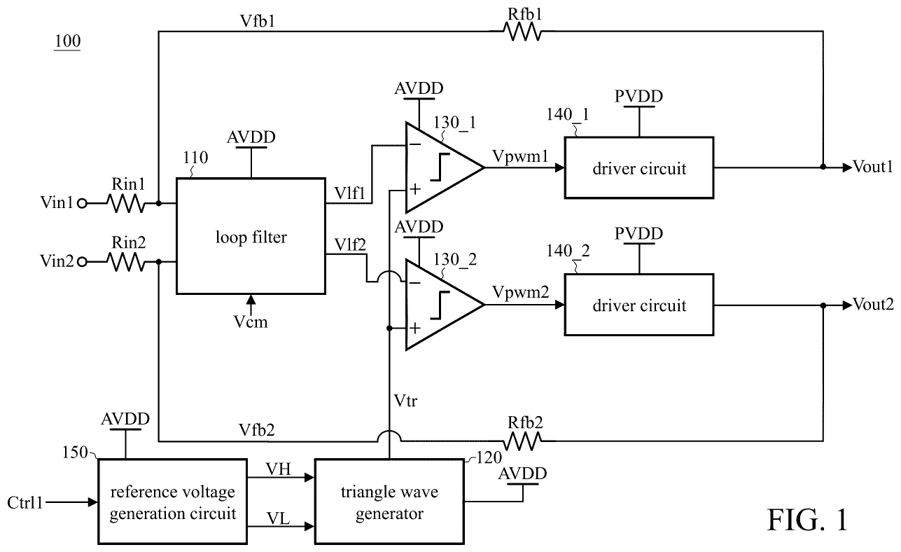

Reference is made to FIG. 1, which is a functional block diagram of a class-D amplifier according to an embodiment of the present invention. The class-D amplifier 100 includes a loop filter 110, a triangle wave generator 120, a comparator 130_1, a comparator 130_2, a driver circuit 140_1, a driver circuit 140_2, a reference voltage generation circuit 150, a resistor Rin1, a resistor Rin2, a resistor Rfb1, and a resistor Rfb2, all of which are coupled to each other. The input signal Vin1 and the input signal Vin2 are the differential input signals of the class-D amplifier 100, and the output signal Vout1 and the output signal Vout2 are the differential output signals of the class-D amplifier 100.

The input signals of the loop filter 110 include the feedback signal Vfb1, the feedback signal Vfb2, the input signal Vin1, and the input signal Vin2. The input signal Vin1 and the input signal Vin2 are respectively received through the resistor Rin1 and the resistor Rin2. The loop filter 110 filters the input signal Vin1, the input signal Vin2, the feedback signal Vfb1, and the feedback signal Vfb2 to generate the filtered signal Vlf1 and the filtered signal Vlf2. The loop filter 110 contains at least one integrator. The common-mode voltage Vcm is the common-mode voltage of the operational amplifier of the integrator at the last stage of the loop filter 110. When the loop filter 110 contains only one integrator, the integrator is the output stage (i.e., the last stage) integrator of the loop filter 110. In the class-D amplifier 100, the common-mode voltage Vcm may be a constant value.

In some embodiments, the resistance value of the resistor Rin1 can be substantially equal to the resistance value of the resistor Rin2, and the resistance value of the resistor Rfb1 can be substantially equal to the resistance value of the resistor Rfb2.

The triangle wave generator 120 generates the triangle wave Vtr according to a high reference voltage VH and a low reference voltage VL.

The comparator 130_1 compares the filtered signal Vlf1 with the triangle wave Vtr to generate a pulse width modulation (PWM) signal Vpwm1. The comparator 130_2 compares the filtered signal Vlf2 with the triangle wave Vtr to generate a PWM signal Vpwm2.

The driver circuit 140_1 is used to generate an output signal Vout1 according to the PWM signal Vpwm1. The resistor Rfb1 is coupled between the output terminal of the driver circuit 140_1 and the input terminal of the loop filter 110. That is to say, one terminal of the resistor Rfb1 receives the output signal Vout1, and the other terminal of the resistor Rfb1 outputs the feedback signal Vfb1.

The driver circuit 140_2 is used to generate the output signal Vout2 according to the PWM signal Vpwm2. The resistor Rfb2 is coupled between the output terminal of the driver circuit 140_2 and the input terminal of the loop filter 110. That is to say, one terminal of the resistor Rfb2 receives the output signal Vout2, and the other terminal of the resistor Rfb2 outputs the feedback signal Vfb2.

The operating principles of the triangle wave generator 120, the comparator 130_1, the comparator 130_2, the driver circuit 140_1, and the driver circuit 140_2 are well known to people having ordinary skill in the art, so further elaboration is omitted for brevity. The driver circuit 140_1 and the driver circuit 140_2 operate according to a power supply voltage PVDD (e.g., 20 volts) to output larger output signals Vout1 and Vout2, while other circuit blocks (e.g., the loop filter 110, the triangle wave generator 120, the comparator 130_1, the comparator 130_2, and the reference voltage generation circuit 150) operate according to a lower power supply voltage AVDD (e.g., 5 volts).

The reference voltage generation circuit 150 is used to provide the high reference voltage VH and the low reference voltage VL, and the reference voltage generation circuit 150 can adjust (generate) the high reference voltage VH and the low reference voltage VL according to the control signal Ctrl1.

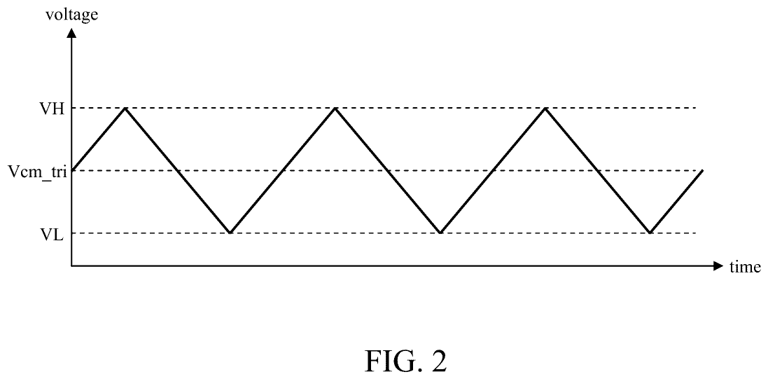

Reference is made to FIG. 2, which is a schematic diagram of a triangle wave. The highest point of the triangle wave is the high reference voltage VH, the lowest point of the triangle wave is the low reference voltage VL, and the middle point of the triangle wave is the reference voltage Vcm_tri. The relationship among the three is shown in equation (1).

$$Vcm\_tri = 0.5 VH + 0.5 VL \qquad ( 1 )$$

Assuming the output signal Vout1 and the output signal Vout2 have a duty cycle of 50%, the relationship among the common-mode voltage Vcm, the high reference voltage VH, and the low reference voltage VL is shown in equation (2).

$$1 - \frac{Vcm - VL}{VH - VL} = 0.5 \qquad ( 2 )$$

The relationship among the high reference voltage VH, the low reference voltage VL, and the GPWM is shown in equation (3), wherein the GPWM can be defined as PVDD/(VH-VL).

$$VH - VL = \frac{PVDD}{GPWM} \qquad ( 3 )$$

According to equations (1) and (2), the duty cycle DC of the output signals Vout1 and Vout2 can be obtained as shown in equation (4).

$$DC = ( 1 - \frac{Vcm - VL}{2 Vcm\_tri - 2 VL} ) \qquad ( 4 )$$

According to equations (1) and (3), equations (5) and equation (6) can be obtained.

$$VH = Vcm\_tri + \frac{1}{2} \times \frac{PVDD}{GPWM} \qquad ( 5 )$$

$$VL = Vcm\_tri - \frac{1}{2} \times \frac{PVDD}{GPWM} \qquad ( 6 )$$

Finally, according to equations (4) and (6), equation (7) can be obtained.

$$DC = 0.5 + \frac{GPWM \times ( Vcm\_tri - Vcm )}{PVDD} \qquad ( 7 )$$

From equation (7), it is known that the duty cycles DC of the output signals Vout1 and Vout2 can be changed by adjusting the reference voltage Vcm_tri and/or the common-mode voltage Vcm. The greater (smaller) the duty cycle DC, the higher (lower) the voltages of the feedback signals Vfb1 and Vfb2. In other words, the invention can ensure that the transistors inside the loop filter 110 operate in the correct region by adjusting the reference voltage Vcm_tri and/or the common-mode voltage Vcm, to avoid errors occurring in the loop filter 110 or even in the entire class-D amplifier 100.

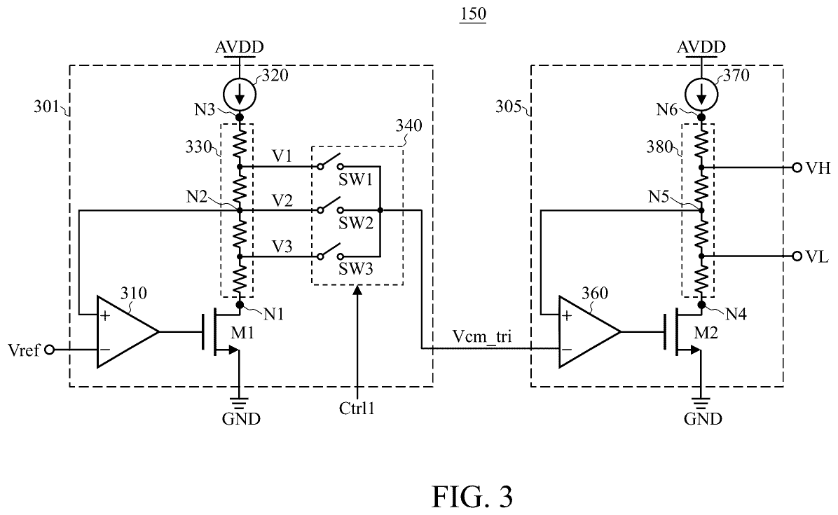

Reference is made to FIG. 3, which is a circuit diagram of the reference voltage generation circuit 150 according to an embodiment of the present invention. The reference voltage generation circuit 150 includes a first voltage generation circuit 301 and a second voltage generation circuit 305. The first voltage generation circuit 301 is controlled by a control signal Ctrl1, and generates a reference voltage Vcm_tri according to a reference voltage Vref. The second voltage generation circuit 305 is coupled to the first voltage generation circuit 301 and is configured to generate the high reference voltage VH and the low reference voltage VL according to the reference voltage Vcm_tri.

The first voltage generation circuit 301 includes a transistor M1, an operational amplifier 310, a current source 320, a voltage divider 330, and a switch group 340.

The transistor M1 is an N-channel Metal-Oxide-Semiconductor Field-Effect Transistor (hereafter referred to as an NMOS transistor). The source of the transistor M1 is coupled or electrically connected to the reference voltage GND; the drain of the transistor M1 (i.e., the node N1) is coupled or electrically connected to the voltage divider 330; the gate of the transistor M1 is coupled or electrically connected to the output terminal of the operational amplifier 310.

The inverting input terminal of the operational amplifier 310 receives the reference voltage Vref; the non-inverting input terminal of the operational amplifier 310 is coupled or electrically connected to the node N2. The voltage at the node N2 is substantially equal to the reference voltage Vref.

The current source 320 is coupled between the power supply voltage AVDD and the node N3 and is configured to provide a current.

One terminal of the voltage divider 330 is coupled or electrically connected to the node N1; the other terminal of the voltage divider 330 is coupled or electrically connected to the node N3. The voltage divider 330 contains multiple resistors, and the node N2 is a node inside the voltage divider 330. In the embodiment of FIG. 3, the voltage divider 330 includes four resistors; two of the resistors are located between the node N1 and the node N2, and the other two of the resistors are located between the node N2 and the node N3. In some embodiments, the four resistors have substantially the same resistance value.

The switch group 340 is coupled or electrically connected to the voltage divider 330 and includes multiple switches (switches SW1 to SW3). The switches are controlled by the control signal Ctrl1. That is to say, the value of the reference voltage Vcm_tri is determined by the control signal Ctrl1. More specifically, the voltage divider 330 provides the candidate voltages V1 to V3 (which are respectively received by the switches SW1 to SW3), and the switch group 340 selects one of the candidate voltages according to the control signal Ctrl1 to output as the reference voltage Vcm_tri.

The second voltage generation circuit 305 includes a transistor M2, an operational amplifier 360, a current source 370, and a voltage divider 380.

The transistor M2 is an NMOS transistor. The source of the transistor M2 is coupled or electrically connected to the reference voltage GND; the drain of the transistor M2 (i.e., the node N4) is coupled or electrically connected to the voltage divider 380; the gate of the transistor M2 is coupled or electrically connected to the output terminal of the operational amplifier 360.

The inverting input terminal of the operational amplifier 360 receives the reference voltage Vcm_tri; the non-inverting input terminal of the operational amplifier 360 is coupled or electrically connected to the node N5. The voltage at the node N5 is substantially equal to the reference voltage Vcm_tri.

The current source 370 is coupled between the power supply voltage AVDD and the node N6 and is configured to provide a current.

One terminal of the voltage divider 380 is coupled or electrically connected to the node N4; the other terminal of the voltage divider 380 is coupled or electrically connected to the node N6. The voltage divider 380 contains multiple resistors, and the node N5 is a node inside the voltage divider 380. In the embodiment of FIG. 3, the voltage divider 380 includes four resistors; two of the resistors are located between the node N4 and the node N5, and the other two of the resistors are located between the node N5 and the node N6. In some embodiments, the four resistors have substantially the same resistance value.

The high reference voltage VH and the low reference voltage VL are two voltages generated from the power supply voltage AVDD after it is divided by the voltage divider 380.

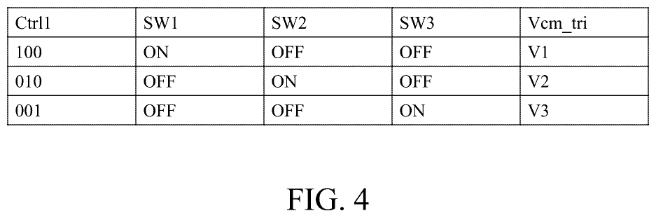

Reference is made to FIG. 4, which shows the relationship between the control signal Ctrl1 and the reference voltage Vcm_tri. When the control signal Ctrl1 equals 100₂, the switch SW1 is turned on (“ON”) and the switch SW2 and the switch SW3 are turned off (“OFF”), making the reference voltage Vcm_tri equal to the candidate voltage V1. When the control signal Ctrl1 equals 010₂, the switch SW2 is turned on and the switch SW1 and the switch SW3 are turned off, making the reference voltage Vcm_tri equal to the candidate voltage V2. When the control signal Ctrl1 equals 001₂, the switch SW3 is turned on and the switch SW1 and the switch SW2 are turned off, making the reference voltage Vcm_tri equal to the candidate voltage V3. In the embodiment of FIG. 3, V1>V2>V3. At any time, only one of the switches SW1 to SW3 is turned on.

In summary, the class-D amplifier 100 of the present invention can adjust the duty cycle DC of the output signal Vout1 and the output signal Vout2 by adjusting the high reference voltage VH and the low reference voltage VL (refer to equation (7)), so as to control the feedback signal Vfb1 and the feedback signal Vfb2 within an appropriate voltage range according to the actual operating environment, thereby improving the stability of the class-D amplifier 100.

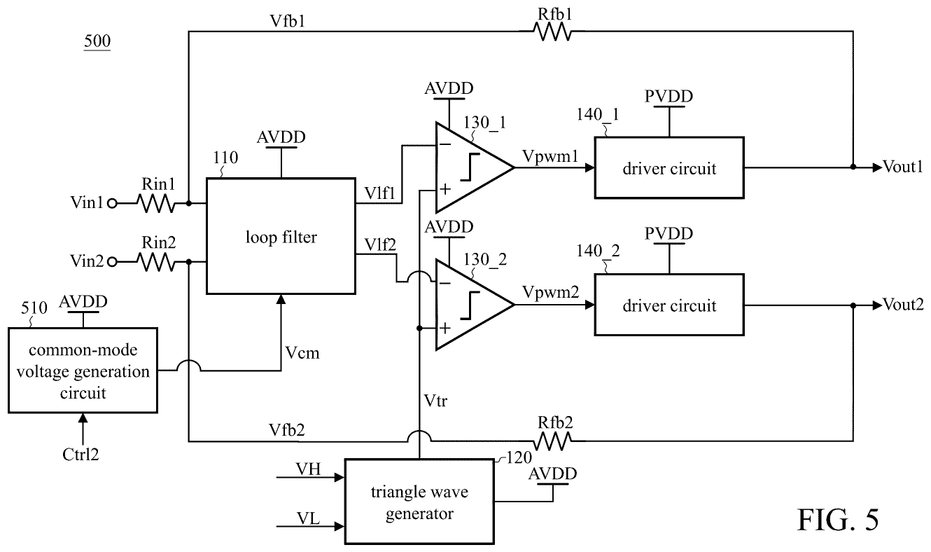

Reference is made to FIG. 5, which is a functional block diagram of a class-D amplifier 500 according to another embodiment of the present invention. The class-D amplifier 500 is similar to the class-D amplifier 100, except that the class-D amplifier 500 does not include the reference voltage generation circuit 150, but instead includes the common-mode voltage generation circuit 510. In the class-D amplifier 500, the high reference voltage VH and the low reference voltage VL may be fixed values. The common-mode voltage generation circuit 510 is coupled or electrically connected to the loop filter 110 to provide the common-mode voltage Vcm to the loop filter 110.

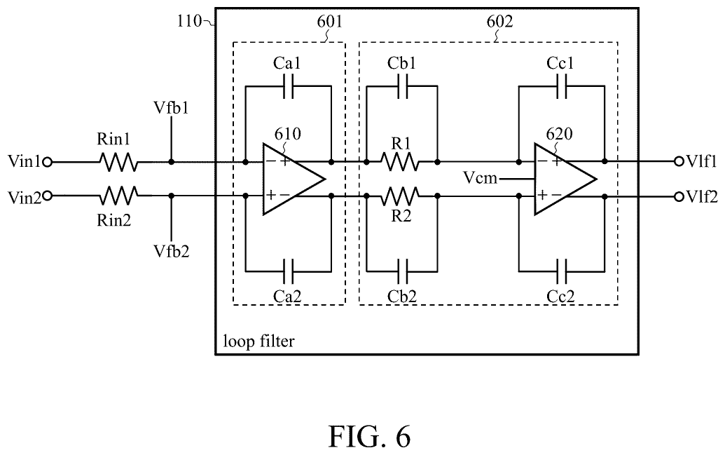

Reference is made to FIG. 6, which is a circuit diagram of the loop filter 110 according to an embodiment of the present invention. The loop filter 110 includes an operational amplifier 610, an operational amplifier 620, a resistor R1, a resistor R2, a capacitor Ca1, a capacitor Ca2, a capacitor Cb1, a capacitor Cb2, a capacitor Cc1, and a capacitor Cc2, all of which are coupled to each other.

The loop filter 110 contains two stages of integrators: an integrator 601 and an integrator 602. The first stage (input stage) integrator 601 includes the operational amplifier 610, the capacitor Ca1, and the capacitor Ca2. The second stage (output stage) integrator 602 includes the operational amplifier 620, the resistor R1, the resistor R2, the capacitor Cb1, the capacitor Cb2, the capacitor Cc1, and the capacitor Cc2. The common-mode voltage Vcm in FIG. 5 is the common-mode voltage of the operational amplifier 620. The operating principle of the integrator is well known to people having ordinary skill in the art, so further elaboration is omitted for brevity.

In other embodiments, if the loop filter 110 only includes the integrator 601, then the common-mode voltage Vcm in FIG. 5 is the common-mode voltage of the operational amplifier 610.

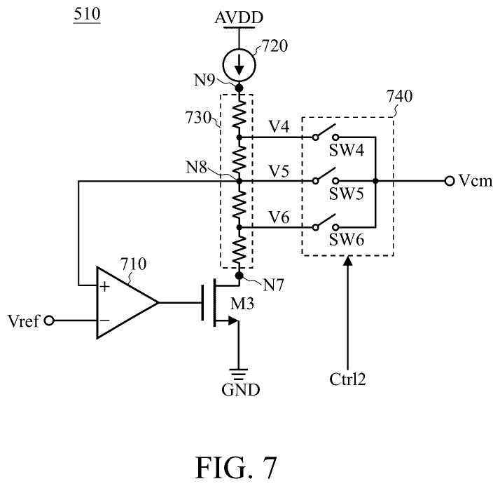

Reference is made to FIG. 7, which is a circuit diagram of a common-mode voltage generation circuit 510 according to an embodiment of the present invention. The common-mode voltage generation circuit 510 is controlled by the control signal Ctrl2, and generates the common-mode voltage Vcm based on the reference voltage Vref. The common-mode voltage generation circuit 510 includes a transistor M3, an operational amplifier 710, a current source 720, a voltage divider 730, and a switch group 740.

The common-mode voltage generation circuit 510 is similar to the first voltage generation circuit 301, wherein the transistor M3, the operational amplifier 710, the current source 720, the voltage divider 730, the switch group 740, the node N7, the node N8, the node N9, the candidate voltage V4, the candidate voltage V5, the candidate voltage V6, the switch SW4, the switch SW5, and the switch SW6 correspond to the transistor M1, the operational amplifier 310, the current source 320, the voltage divider 330, the switch group 340, the node N1, the node N2, the node N3, the candidate voltage V1, the candidate voltage V2, the candidate voltage V3, the switch SW1, the switch SW2, and the switch SW3, respectively.

The control signal Ctrl2 can be used to adjust the magnitude of the common-mode voltage Vcm (refer to FIG. 4). Similarly, at any time, only one of the switches SW4 to SW6 is turned on.

In summary, the class-D amplifier 500 of the present invention can adjust the duty cycle DC of the output signal Vout1 and the output signal Vout2 by adjusting the common-mode voltage Vcm (refer to equation (7)), so as to control the feedback signal Vfb1 and the feedback signal Vfb2 within an appropriate voltage range according to the actual operating environment, thereby improving the stability of the class-D amplifier 500.

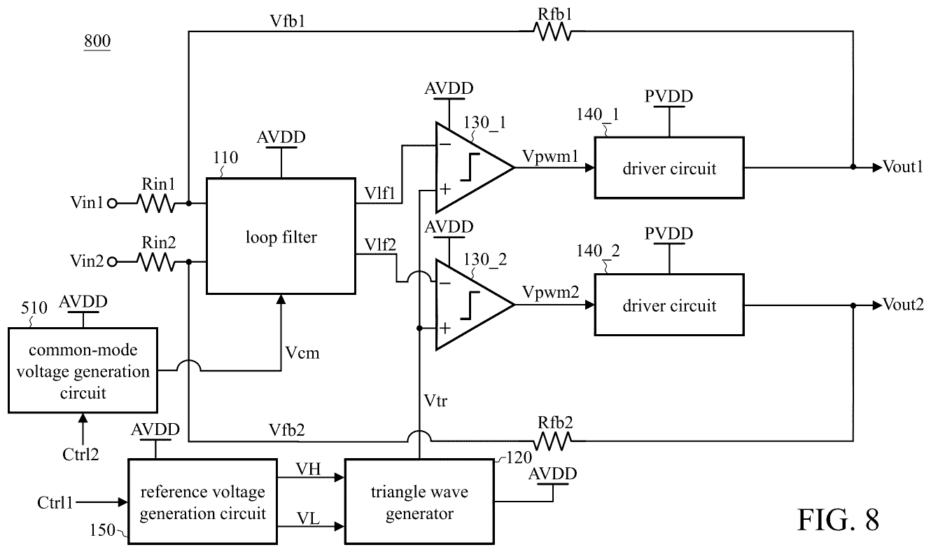

Reference is made to FIG. 8, which is a functional block diagram of a class-D amplifier according to another embodiment of the present invention. The class-D amplifier 800 is a combination of the class-D amplifier 100 and the class-D amplifier 500. More specifically, in the embodiment of FIG. 8, it is possible to simultaneously adjust the reference voltage Vcm_tri of the triangle wave Vtr and the common-mode voltage Vcm of the loop filter 110 through the control signal Ctrl1 and the control signal Ctrl2, respectively. This can increase the flexibility of adjustment, making the class-D amplifier 800 suitable for more diverse operating environments.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A class-D amplifier, comprising:
a first resistor;
a second resistor;
a loop filter coupled to the first resistor and the second resistor and configured to receive a first feedback signal and a second feedback signal, and to receive a first input signal and a second input signal respectively through the first resistor and the second resistor, wherein the loop filter filters the first input signal, the second input signal, the first feedback signal, and the second feedback signal to generate a first filtered signal and a second filtered signal;
a triangle wave generator configured to generate a triangle wave according to a first reference voltage and a second reference voltage;
a first comparator coupled to the loop filter and the triangle wave generator and configured to compare the first filtered signal with the triangle wave to generate a first pulse width modulation (PWM) signal;
a second comparator coupled to the loop filter and the triangle wave generator and configured to compare the second filtered signal with the triangle wave to generate a second PWM signal;
a first driver circuit coupled to the first comparator and configured to generate a first output signal according to the first PWM signal;
a second driver circuit coupled to the second comparator and configured to generate a second output signal according to the second PWM signal;
a third resistor coupled between the first driver circuit and the loop filter;
a fourth resistor coupled between the second driver circuit and the loop filter; and
a reference voltage generation circuit coupled to the triangle wave generator and configured to generate the first reference voltage and the second reference voltage according to a control signal.

2. The class-D amplifier of claim 1, wherein the first driver circuit and the second driver circuit operate according to a first power supply voltage, the loop filter, the triangle wave generator, the first comparator, the second comparator, and the reference voltage generation circuit operate according to a second power supply voltage, and the first power supply voltage is greater than the second power supply voltage.

3. The class-D amplifier of claim 2, wherein the reference voltage generation circuit comprises:
a first voltage generation circuit configured to generate a fourth reference voltage according to a third reference voltage; and
a second voltage generation circuit coupled to the first voltage generation circuit and configured to generate the first reference voltage and the second reference voltage according to the fourth reference voltage.

4. The class-D amplifier of claim 3, wherein the first voltage generation circuit comprises:
a transistor having a first terminal, a second terminal, and a third terminal, wherein the first terminal is coupled to a fifth reference voltage, and the second terminal is coupled to a first node;
an operational amplifier having a first input terminal, a second input terminal, and an output terminal, wherein the first input terminal receives the third reference voltage, the second input terminal is coupled to a second node, and the output terminal is coupled to the third terminal of the transistor;
a current source coupled to the second power supply voltage and a third node;
a voltage divider coupled between the first node and the third node and configured to generate a plurality of candidate voltages, wherein the second node is a node inside the voltage divider; and
a switch group coupled to the voltage divider and configured to select one of the plurality of candidate voltages as the fourth reference voltage according to the control signal.

5. The class-D amplifier of claim 4, wherein the switch group comprises:
a first switch coupled to the voltage divider and configured to receive one of the plurality of candidate voltages; and
a second switch coupled to the voltage divider and configured to receive one of the plurality of candidate voltages;
wherein one of the first switch and the second switch is turned on, and the first switch and the second switch are not turned on at a same time.

6. The class-D amplifier of claim 3, wherein the second voltage generation circuit comprises:
a transistor having a first terminal, a second terminal, and a third terminal, wherein the first terminal is coupled to a fifth reference voltage, and the second terminal is coupled to a first node;
an operational amplifier having a first input terminal, a second input terminal, and an output terminal, wherein the first input terminal receives the fourth reference voltage, the second input terminal is coupled to a second node, and the output terminal is coupled to the third terminal of the transistor;
a current source coupled to the second power supply voltage and a third node; and
a voltage divider coupled between the first node and the third node and configured to provide the first reference voltage and the second reference voltage, wherein the second node is a node inside the voltage divider.

7. The class-D amplifier of claim 3, wherein a magnitude of the first feedback signal is related to a first duty cycle of the first output signal, a magnitude of the second feedback signal is related to a second duty cycle of the second output signal, and the first duty cycle and the second duty cycle are adjusted by changing the fourth reference voltage.

8. The class-D amplifier of claim 2, wherein the control signal is a first control signal, and the class-D amplifier further comprises:
a common-mode voltage generation circuit coupled to the loop filter and configured to generate a common-mode voltage according to a second control signal;
wherein the loop filter comprises an integrator, the integrator comprises an operational amplifier, and the common-mode voltage is the common-mode voltage of the operational amplifier.

9. The class-D amplifier of claim 8, wherein the integrator is a part of an output stage of the loop filter.

10. The class-D amplifier of claim 8, wherein the operational amplifier is a first operational amplifier, and the common-mode voltage generation circuit comprises:
a transistor having a first terminal, a second terminal, and a third terminal, wherein the first terminal is coupled to a third reference voltage, and the second terminal is coupled to a first node;
a second operational amplifier having a first input terminal, a second input terminal, and an output terminal, wherein the first input terminal receives a fourth reference voltage, the second input terminal is coupled to a second node, and the output terminal is coupled to the third terminal of the transistor;
a current source coupled to the second power supply voltage and a third node;
a voltage divider coupled between the first node and the third node and configured to generate a plurality of candidate voltages, wherein the second node is a node inside the voltage divider; and
a switch group coupled to the voltage divider and configured to select one of the plurality of candidate voltages as the common-mode voltage according to the second control signal.

11. The class-D amplifier of claim 10, wherein the switch group comprises:
a first switch coupled to the voltage divider and configured to receive one of the plurality of candidate voltages; and
a second switch coupled to the voltage divider and configured to receive one of the plurality of candidate voltages;
wherein one of the first switch and the second switch is turned on, and the first switch and the second switch are not turned on at a same time.

12. The class-D amplifier of claim 8, wherein a magnitude of the first feedback signal is related to a first duty cycle of the first output signal, a magnitude of the second feedback signal is related to a second duty cycle of the second output signal, and the first duty cycle and the second duty cycle are adjusted by changing the common-mode voltage.

13. The class-D amplifier of claim 1, wherein a terminal of the third resistor receives the first output signal, another terminal of the third resistor outputs the first feedback signal, a terminal of the fourth resistor receives the second output signal, and another terminal of the fourth resistor outputs the second feedback signal.

14. A class-D amplifier, comprising:
a first resistor;
a second resistor;
a loop filter coupled to the first resistor and the second resistor and configured to receive a first feedback signal and a second feedback signal, and to receive a first input signal and a second input signal respectively through the first resistor and the second resistor, wherein the loop filter filters the first input signal, the second input signal, the first feedback signal, and the second feedback signal to generate a first filtered signal and a second filtered signal;
a triangle wave generator configured to generate a triangle wave according to a first reference voltage and a second reference voltage;
a first comparator coupled to the loop filter and the triangle wave generator and configured to compare the first filtered signal with the triangle wave to generate a first pulse width modulation (PWM) signal;
a second comparator coupled to the loop filter and the triangle wave generator and configured to compare the second filtered signal with the triangle wave to generate a second PWM signal;
a first driver circuit coupled to the first comparator and configured to generate a first output signal according to the first PWM signal;
a second driver circuit coupled to the second comparator and configured to generate a second output signal according to the second PWM signal;
a third resistor coupled between the first driver circuit and the loop filter;
a fourth resistor coupled between the second driver circuit and the loop filter; and
a common-mode voltage generation circuit coupled to the loop filter and configured to generate a common-mode voltage according to a control signal;
wherein the loop filter comprises an integrator, the integrator comprises an operational amplifier, and the common-mode voltage is the common-mode voltage of the operational amplifier.

15. The class-D amplifier of claim 14, wherein the operational amplifier is a first operational amplifier, and the common-mode voltage generation circuit comprises:
a transistor having a first terminal, a second terminal, and a third terminal, wherein the first terminal is coupled to a third reference voltage, and the second terminal is coupled to a first node;
a second operational amplifier having a first input terminal, a second input terminal, and an output terminal, wherein the first input terminal receives a fourth reference voltage, the second input terminal is coupled to a second node, and the output terminal is coupled to the third terminal of the transistor;
a current source coupled to a power supply voltage and a third node;
a voltage divider coupled between the first node and the third node and configured to generate a plurality of candidate voltages, wherein the second node is a node inside the voltage divider; and
a switch group coupled to the voltage divider and configured to select one of the plurality of candidate voltages as the common-mode voltage according to the control signal.

16. The class-D amplifier of claim 15, wherein the switch group comprises:
a first switch coupled to the voltage divider and configured to receive one of the plurality of candidate voltages; and
a second switch coupled to the voltage divider and configured to receive one of the plurality of candidate voltages;
wherein one of the first switch and the second switch is turned on, and the first switch and the second switch are not turned on at a same time.

17. The class-D amplifier of claim 14, wherein the integrator is a part of an output stage of the loop filter.

18. The class-D amplifier of claim 14, wherein a magnitude of the first feedback signal is related to a first duty cycle of the first output signal, a magnitude of the second feedback signal is related to a second duty cycle of the second output signal, and the first duty cycle and the second duty cycle are adjusted by changing the common-mode voltage.

19. The class-D amplifier of claim 14, wherein a terminal of the third resistor receives the first output signal, another terminal of the third resistor outputs the first feedback signal, a terminal of the fourth resistor receives the second output signal, and another terminal of the fourth resistor outputs the second feedback signal.
